(19) United States
(12) Patent Application Publication
(10) Pub. No.: US 2017/0086298 A1
(43) Pub. Date: Mar. 23, 2017

(54) SUBSTRATE INCLUDING STRUCTURES TO COUPLE A CAPACITOR TO A PACKAGED DEVICE AND METHOD OF MAKING SAME

(71) Applicants: Tin Poay Chuah, Bayan Lepas (MY); Min Suet Lim, Bayan Lepas (MY); Ping Ping Ooi, Butterworth (MY); Eng Huat Goh, Ayer Itam (MY); See Chin Chow, Gelugor (MY)

(72) Inventors: Tin Poay Chuah, Bayan Lepas (MY); Min Suet Lim, Bayan Lepas (MY); Ping Ping Ooi, Butterworth (MY); Eng Huat Goh, Ayer Itam (MY); See Chin Chow, Gelugor (MY)

(21) Appl. No.: 14/863,380

(22) Filed: Sep. 23, 2015

(51) Int. Cl. H05K 1/18; H05K 3/32; H05K 3/30; H05K 1/11; H05K 3/00

(52) U.S. Cl. CPC H05K 1/183; H05K 1/181; H05K 1/115; H05K 3/0011; H05K 3/301; H05K 3/32; H05K 2201/10515; H05K 2201/10015

(57) ABSTRACT

Techniques and mechanisms to provide interconnect structures of a substrate such as a printed circuit board. In an embodiment, a first side of a substrate has disposed thereon a hardware interface contacts to couple the substrate to a packaged IC device. The contacts define a footprint area, where an overlap region of the substrate is defined by a projection of the footprint area from the first side to a second side of the substrate. The substrate forms a recess extending from one of the first side and the second side. In another embodiment, at least part of the recess is within the overlap region, and interconnect structures of the substrate facilitate connection between the packaged IC device and a capacitor disposed at least partially in the recess. Positioning of the capacitor within the overlap region enables improvements in substrate space efficiency, power delivery and/or signal noise.

### BACKGROUND

1. Technical Field

Embodiments discussed herein relate generally to the field of printed circuit board manufacturing, and more specifically, but not exclusively, to techniques and mechanisms for delivering power with a printed circuit board.

2. Background Art

In the field of integrated circuit technology, a number of passive devices may be physically and electrically coupled to a substrate such as a printed circuit board (PCB). Such passive devices may include capacitors which may serve a number of purposes including, for example, providing a source of transient power, filtering, signal decoupling, generating oscillation, and fine-tuning. In most instances, these capacitors may be coupled to a PCB surface, by a surface-mount method or by pin connection.

Although surface mounting of capacitors may work well for some applications, the trend toward increasing capacitance demands as well as the ubiquitous shrinking of packages and boards may render current capacitance solutions problematic. Moreover, as successive generations of integrated circuitry continue to scale in terms of size, signal bandwidth, voltage, etc. there is an attendant demand for the platforms in which such circuitry operates to support high bit-rate, power efficient signaling. The need for mechanisms to reduce sources of noise is one aspect of this demand.

### BRIEF DESCRIPTION OF THE DRAWINGS

The various embodiments of the present invention are illustrated by way of example, and not by way of limitation, in the figures of the accompanying drawings and in which:

FIG. 1 is a perspective view of a system to provide capacitance for operation of a packaged integrated circuit (IC) device according to an embodiment.

FIG. 2 is a flow diagram illustrating elements of a method to fabricate structures of a substrate according to an embodiment.

FIG. 3A is a cross-sectional view of a system to provide capacitance for operation of a packaged IC device according to an embodiment.

FIG. 3B is a cross-sectional view of a system to provide capacitance for operation of a packaged IC device according to an embodiment.

FIG. 4 shows cross-sectional views of systems each to provide capacitance for a respective packaged IC device according to a corresponding embodiment.

FIG. 5 is a perspective view of a system to provide capacitance for operation of a packaged IC device according to an embodiment.

FIG. 6A shows cross-sectional views of processing to fabricate structures of a printed circuit board according to an embodiment.

FIG. 6B shows cross-sectional views of processing to fabricate structures of a printed circuit board according to an embodiment.

FIG. 7 illustrates a computing device in accordance with one implementation of the invention.

FIG. 8 illustrates a block diagram of an exemplary computer system, in accordance with an embodiment of the present invention.

FIG. 9 is an interposer implementing one or more embodiments of the invention.

FIG. 10 is a computing device built in accordance with an embodiment of the invention.

### DETAILED DESCRIPTION

Embodiments discussed herein variously include techniques and/or mechanisms to enable coupling of a circuit element, such as a capacitor, to a packaged integrated circuit (IC) device via a substrate. A substrate according to one embodiment includes or has disposed thereon a hardware interface to couple the substrate to a package that, for example, includes a system-in-package, a processor package, a memory package or any of a variety of other packaged IC devices. The substrate—e.g., a printed circuit board—may form a recess structure that is to receive a circuit element (such as a capacitor), where a contact within the recess structure is configured to couple the substrate to that circuit element while the circuit element is located at least partially within the recess structure.

Contacts of the hardware interface may define an area (referred to herein as a “footprint area,” or simply “footprint”) on a first side of the substrate—e.g., where a portion of the substrate (referred to herein as an “overlap region”) is defined by a projection of that area from the first side to an opposite side of the substrate. In an embodiment, the recess structure extends from one of these sides within the overlap region. The location of the recess at least partially within the overlap region may reduce coupling and/or otherwise provide for power delivery, signal noise and/or other characteristics that, for example, is/are better than corresponding characteristics variously provided by existing printed circuit board architectures. Certain features of various embodiments are described herein with reference to recess structures of a printed circuit board (PCB), the recess structures configured to accommodate coupling of a capacitor to the PCB. However, such description may be extended to additionally or alternatively apply to a recess structure of any of a variety of other substrates and/or to the coupling of any of a variety of other circuit elements to a substrate via such recess structure.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices including one or more packaged IC devices.

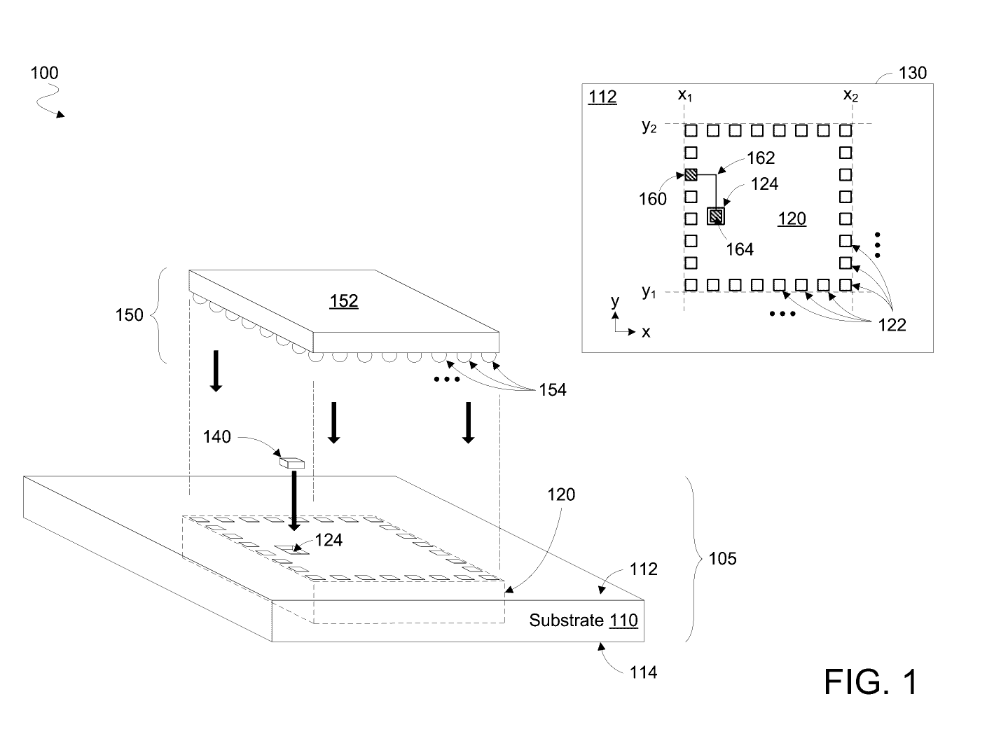

FIG. 1 is an exploded view illustrating elements of a system 100 to provide connection between a circuit element and a packaged IC device according to an embodiment. System 100 may include a processing-capable platform and/or provide functionality to operate as a component of such a platform. In the illustrative embodiment shown, system 100 includes a device 105, a packaged IC device 150 and a capacitor 140, where packaged IC device 150 is to couple to capacitor 140 via device 105. Some embodiments are implemented entirely by device 105—e.g., independent of packaged IC device 150 and/or capacitor 140 being connect to device 105.

A substrate 110 (e.g., a motherboard or other PCB) of device 105 may include any of a variety of substrate materials and/or structures suitable to support coupling to, and operation with, one or more packaged IC devices. For example, materials used in conventional PCB manufacture techniques may be adapted to fabricate substrate 100—e.g., where such materials include, but are not limited to, any of various FR4 materials, composite epoxy materials (such as CEM-3), epoxy resins, polyimides, triazine resins and/or the like. Alternatively or in addition, substrate 110 may include any of a variety of materials adapted from conventional techniques for fabricating flexible circuitry, semi-rigid circuitry or the like. Substrate 100 may have disposed therein one or more vias, traces, metallization layers and/or other interconnect structures (not shown) to enable connection between components in substrate 110 and/or between devices substrate 110 and another device.

In one embodiment, substrate 110 includes sides 112, 114 that are opposite to one another, and a hardware interface is disposed (for example) on side 112. Such a hardware interface may include a plurality of contacts 122 comprising conductive pins, pads, balls and/or any of a variety of other such connection hardware. The hardware interface may be configured to couple the substrate 110 to a package such as the illustrative packaged IC device 150 of system 100. In the embodiment shown, packaged IC device 150 includes package material 152 that, for example, has disposed therein one or more IC chips (not shown), active components, passive components, microelectromechanical systems (MEMS) and/or any of a variety of additional or alternative integrated circuitry. Package material 152 may include any of a variety of materials known in the art for packaging integrated circuitry. Examples of such materials include, but are not limited to, an epoxy, polymer, resin, plastic, ceramic etc.

A hardware interface of packaged IC device 150 may comprise a plurality of contacts 154 that correspond to the plurality of contacts 122. For example, plurality of contacts 154 may be capable of alignment for coupling each to a respective one for the plurality of contacts 122. In the illustrative embodiment shown, plurality of contacts 122 includes an arrangement of pads, and plurality of contacts 154 includes a ball grid array. However, certain embodiments are not limited in this regard, and the particular type, number and arrangement of the plurality of contacts 122—as well as the type, number and arrangement of the plurality of contacts 154—is merely illustrative. In other embodiments, one or both hardware interfaces may include respective contacts that are fewer or greater in number and/or differently arranged.

The locations of the plurality of contacts 122 may define an area in side 112 that is referred to herein as a footprint. As used herein with respect to a substrate, “footprint” (or “footprint area”) refers to a portion of a side of the substrate that is defined by a closed loop—e.g., the curve including curved side portions and/or linear side portions—that conforms to a plurality of hardware interface contacts on that side and that forms an outer boundary around that plurality of contacts. As illustrated in detail view 130, the plurality of contacts 120 are formed on an x-y plane of side 112, where the footprint of the plurality of contacts 120 extends between a left-most side x₁ and a right-most side x₂ of the plurality of contacts 120 along an x-axis of the x-y plane, as well as between a lower-most side y₁ and an upper-most side y₂ of the plurality of contacts 120 along a y-axis of the x-y plane. A footprint may have any of a variety of other shapes and or sizes, according to different embodiments. Alternatively or in addition, a footprint may be defined, for example, by only a subset of contacts of a hardware interface.

In an embodiment, substrate enables connection between a packaged device and a capacitor, crystal oscillator or other circuit element—e.g., where such connection provides for improved space efficiency, power delivery and/or signal noise characteristics. By way of illustration and not limitation, structures of substrate 110 may form a recess 124 that extends from an opening at one of sides 112, 114 toward the other of sides 112, 114. The recess 124 may at least partially extend into a region (referred to herein as an “overlap region”) of substrate 110 that is defined at least in part by the footprint of contacts 122. As used herein with respect to a substrate, “overlap region” refers to a 3-dimensional portion of the substrate that is defined by a projection of a footprint from one side of the substrate to an opposite side of the substrate. An overlap region may extend from a plane including one of the substrate sides extends to another plane in which the other substrate side extends. The overlap region may be defined by a projection of the footprint at least insofar as an edge of the footprint defines at least in part a corresponding side of the overlap region, where such a side extends linearly from that footprint edge—e.g., in a direction perpendicular to the plane that includes the footprint. In the example embodiment of system 100, an overlap region 120 of substrate 110 is defined by a projection of the footprint for the plurality of contacts 122 (that is, the area of side 112 from x₁ to x₂, and from y₁ to y₂) perpendicularly from the plane of side 112 through to the plane of side 114. At any point of the footprint, the projection may be perpendicular to the plane of side 112 at that point. The illustrative overlap region 120 includes the footprint area on side 112 and another corresponding area (not shown) on side 114.

Substrate 110 may have disposed therein an interconnect 162 (e.g., including one or more trace portions, vias and/or other conductive structures) that provides a path to couple packaged IC device 152 to a circuit element such as the illustrative capacitor 140. By way of illustration and not limitation, one end of interconnect 162 may couple directly to a first contact 160 of the plurality of contacts 122, where another end of interconnect 162 couples directly to another contact 164 that is disposed within recess 124. First contact 160 may be the closest one of contacts 122 to recess 124, although certain embodiments are not limited in this regard. Location of at least part of recess 124 (and thus capacitor 140) within overlap region 120 aids, for example, in improved decoupling between structures that interconnect capacitor 140 and circuitry in packaged IC device 150. Such structures may further include, for example, another interconnect (not shown) disposed in substrate 110—e.g., where the other interconnect is coupled between another one of the plurality of contacts 122 and an additional contact (not shown) disposed in recess 124. Where two contacts are disposed in recess 124, the two contacts may be configured—for example—to variously couple each to a respective contact (not shown) of capacitor 140.

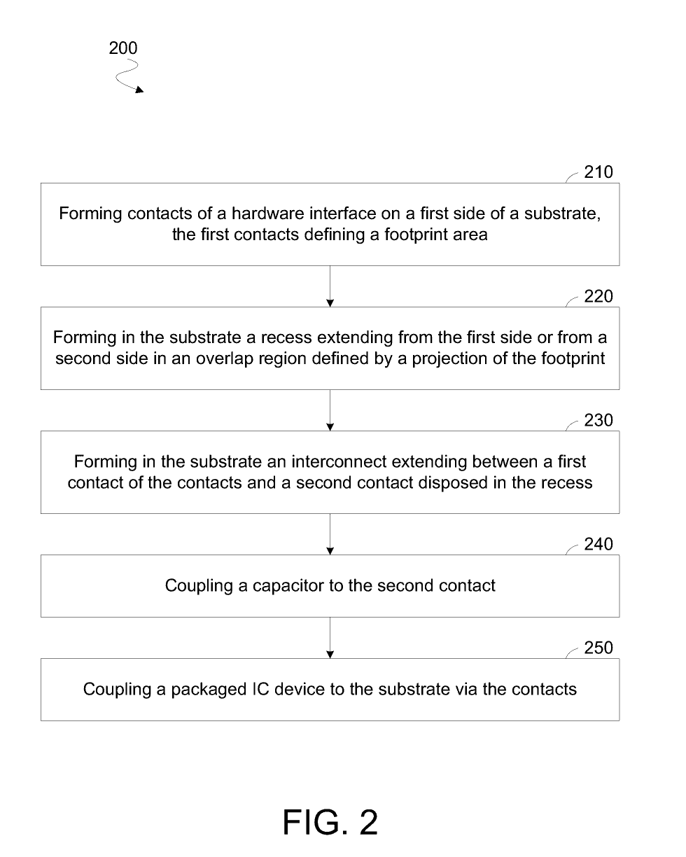

FIG. 2 illustrates elements of a method according to an embodiment to enable connection between a package and a circuit element, such as a capacitor, via a PCB or other substrate. Performance of method 200 may include, for example, operations to fabricate substrate 110 and, in some embodiments, one or more other elements of system 100.

Method 200 may include, at 210, forming contacts of a first hardware interface on a first side of a substrate, the contacts defining a footprint area. For example, the first side (e.g., side 112) may extend in a first plane—e.g., where a second side of the substrate extends in a second plane parallel to the first (curved or flat) plane, and where the contacts formed at 210 define a footprint area in that first plane. The first hardware interface (e.g., including contacts 122) may be configured to couple the substrate to a second hardware interface of a package, such as packaged IC device 150.

In an embodiment, method 200 further comprises, at 220, forming in the substrate a recess extending, from the first side or from a second side of the substrate, in an overlap region defined by a projection of the footprint. In one embodiment, the projection of the footprint includes a projection from a point at the first side to the second side in a direction that is perpendicular to the first plane at that point. Where the recess extends from the second side into substrate, a floor of the recess may be closer to the first side than to the second side. Although some embodiments are not limited in this regard, the recess region may be defined by sidewall structures of the substrate, wherein all sidewalls of the substrate that define part of the recess are within the overlap region.

In one embodiment, the contacts formed at 210 include a first plurality of contacts and a second plurality of contacts, wherein the recess formed at 220 includes a trench extending between the first plurality of contacts and the second plurality of contacts. For example, such a trench may form a closed loop that surrounds the first plurality of contacts.

Method 200 may further comprise, at 230, forming in the substrate an interconnect extending between a first contact of the contacts formed at 210 and a second contact disposed in the recess. The recess formed at 230 may be configured to receive a capacitor (or other circuit element), wherein the second contact disposed in the recess is configured to couple the substrate to that capacitor (element). The recess may also have disposed therein another contact configured to couple such a capacitor to a different one of the contacts formed at 210 or, for example, to a reference potential. The interconnect formed at 230 may include, for example, a via that is directly coupled to the first contact and is also directly coupled to the second contact. In some embodiment, method 200 further comprises operations (not shown) including forming in the substrate another interconnect extending between another contact of the contacts formed at 210 and a third contact disposed in a recess formed in the substrate, wherein the third contact is configured to couple to the capacitor.

Some embodiments include processing, such as that performed at 210, 220, 230, to fabricate a substrate and/or structures in and/or on the substrate. Other embodiments additionally or alternatively include operations to couple one or more devices to the substrate after such fabrication. For example, after the receiving of a substrate fabricated according to operations 210, 220, 230—method 200 may perform, at 240, soldering or otherwise coupling a capacitor (or other circuit element) to the second contact disposed in the recess. In an embodiment, the capacitor may be partially or entirely disposed in the recess after coupling to the second contact. Method 240 may further comprise, at 250, coupling a packaged IC device (e.g., packaged IC device) to the substrate via the contacts formed at 210.

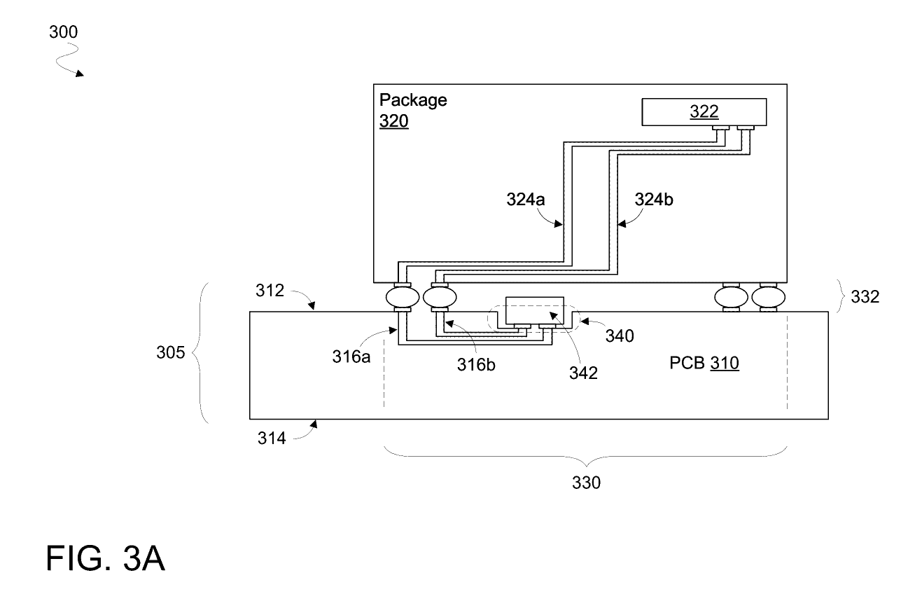

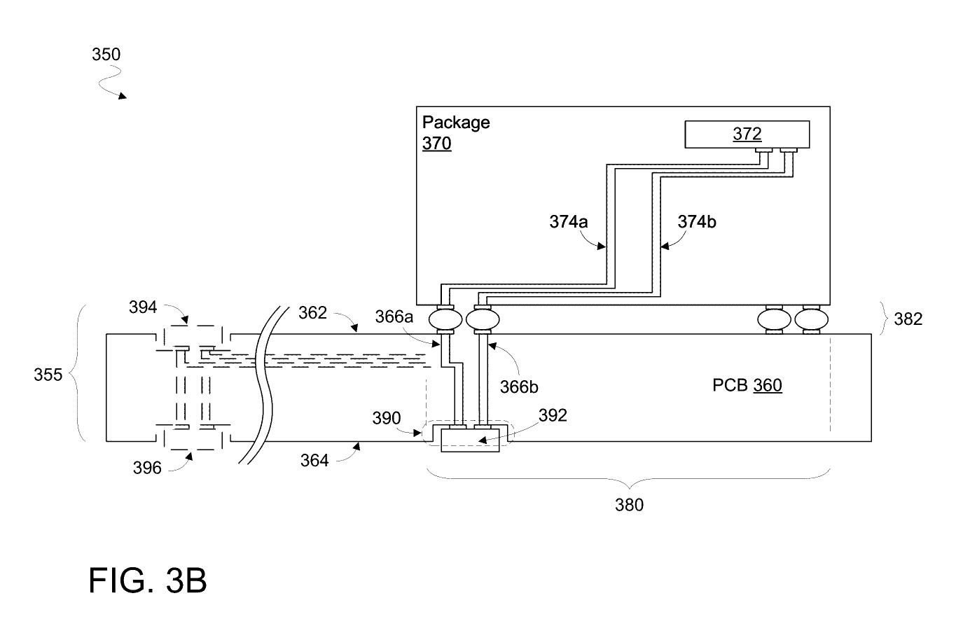

FIG. 3A illustrates elements of a system 300 to couple a packaged device to a capacitor via a substrate according to an embodiment. In the illustrative embodiment shown, system 300 includes a device 305, a package 320 and a capacitor 342, where package 320 and capacitor 342 are coupled to one another via a PCB 310 of device 305. System 300 may include some or all of the features of system 100—e.g., where device 305, package 320 and capacitor 342 correspond functionally to device 105, packaged IC device 150 and capacitor 140. Device 305—and, in some embodiments, other elements of system 300—may be manufactured, for example, by operations of method 200. Some embodiments are implemented entirely by device 305—e.g., independent of package 320 and/or capacitor 342 being coupled to device 305.

PCB 310 may have opposing sides 312, 314 each extending in a respective plane. Package 320 may be coupled to substrate 310 via contacts 332 of a hardware interface disposed on side 312. Contacts 332 may define a footprint in the plane of side 312—e.g., where an overlap region 330 of substrate 310 is defined by a projection of that footprint from side 312 through to side 314.

In an embodiment, substrate 310 forms a recess 340 that, for example, extends from an opening at side 312 in a direction toward side 314. The recess 340 may have disposed therein one or more contacts to enable coupling of substrate 310 to a circuit element such as the illustrative capacitor 342. The recess 340 may be at least partially located within overlap region 330, where capacitor 342 is at least partially located in recess 340 and overlap region 330 while coupled to PCB 310. In the example embodiment of system 300, recess 340 is entirely within overlap region 330. The location of some or all of recess 340 within overlap region 330 may contribute to capacitor 342 being in close proximity to IC circuitry of package 320. Such proximity may allow for improved space utilization, power delivery and/or signal noise characteristics—e.g., as compared to conventional PCB architectures for coupling capacitors to packaged devices.

For example, package 320 may include one or more IC die and paths to variously couple the one or more IC die to PCB 310. In the illustrative embodiment shown, an IC die 322 of package 320 is coupled via paths 324a, 324b (including respective vias, traces and/or other interconnect structures) to respective contacts of hardware interface 332. Paths 324a, 324b may be coupled to contacts 332, for example, to provide IC die 322 with a supply voltage and a reference potential (e.g., a ground) from PCB 310, although certain embodiments are not limited in this regard.

In an embodiment, one or more contacts of device 305 are disposed in recess 340—e.g., where one or more interconnects formed in PCB 310 couple such one or more contacts each to a respective one of contacts 332. For example, contacts 332 may variously couple paths 324a, 324b to respective interconnects 316a, 316b of PCB 310, which in turn couple paths 324a, 324b each to a respective one of two contacts in recess 340. The two contacts in recess 340 may in turn be coupled each to a respective terminal of capacitor 342. The interconnects 316a, 316b may be further coupled each to a respective one of conductive structures (e.g., including traces, planes, vias and/or the like—not shown) in PCB 360, where the conductive structures are each to provide a different respective potential (e.g., including a supply voltage and a reference potential) or a different respective signal.

In such an embodiment, the shaded region between paths 324a, 324b and the shaded region between interconnects 316a, 316b represent a loop inductance region where coupling between two potentials (and/or signals, etc.) may result in inefficient signal communication, poor power delivery and/or the like. By utilizing space in overlap region 330 to locate a decoupling capacitor (or other such circuit element), certain embodiments provide for significant reduction in the overall size of this loop inductance region. This may enable a shorted ground return path and improved efficiency in decoupling capacitance that, for example, improves power delivery performance by PCB 310 (or other such substrate). Alternatively or in addition, use of overlap region 330 to locate capacitor 342 may reduce PCB area constraints. Such improvements may allow for the use of smaller and/or fewer decoupling capacitors, for example.

FIG. 3B illustrates elements of a system 350 according to another illustrative embodiment, the system 350 including a device 355, a package 370 and a capacitor 392, where package 370 and capacitor 392 are coupled to one another via a PCB 360 of device 355. System 350 may include features of system 100 and/or system 300—e.g., where device 355, package 370 and capacitor 392 correspond functionally to device 305, packaged IC device 320 and capacitor 342. In the illustrative embodiment of system 350, a substrate 360 of device 355 has opposing sides 362, 364 each extending in a respective plane. Contacts 382 of a hardware interface disposed on side 362 may define a footprint—e.g., where an overlap region 380 of substrate 360 is defined by a projection of that footprint from side 362 to side 364. Substrate 360 may form a recess 390 that extends from an opening in side 364 toward side 362, where the recess 390 extends at least partially in overlap region 380. A capacitor 392 may be located partially or entirely within recess 390 and overlap region 380 while coupled to contacts that are disposed in recess 390. The locating of recess 390 at least partially within overlap region 380 may enable improvements in the operation of a packaged IC device 370 that is to couple to substrate 360 via contacts 382.

For example, one or more interconnects of substrate 360 (such as the illustrative interconnects 366a, 366b) may variously provide each for coupling between a respective contact in recess 390 and a respective one of contacts 382. In an embodiment, an IC die 372 of package 370 is coupled via paths 374a, 374b to respective ones of contacts 382—e.g, where paths 374a, 374b are coupled to provide IC die 372 with a supply voltage and a reference potential from PCB 360. Accordingly, paths 374a, 374b may be coupled, respectively, to interconnects 366a, 366b via contacts 382. A loop inductance region is represented in FIG. 3B by a shaded area between paths 374a, 374b and another shaded area between interconnects 366a, 366b. Certain embodiments variously reduce the size of such as loop inductance region by utilizing overlap region 380 to locate a decoupling capacitor 392 (or other such circuit element). By contrast, positioning a decoupling capacitor some distance away at a location outside of overlap region 380 may result in a comparatively long ground return path, inefficient decoupling capacitance and/or the like. The positions 394, 396 shown in FIG. 3B illustrate relatively less efficient locations for a decoupling capacitor.

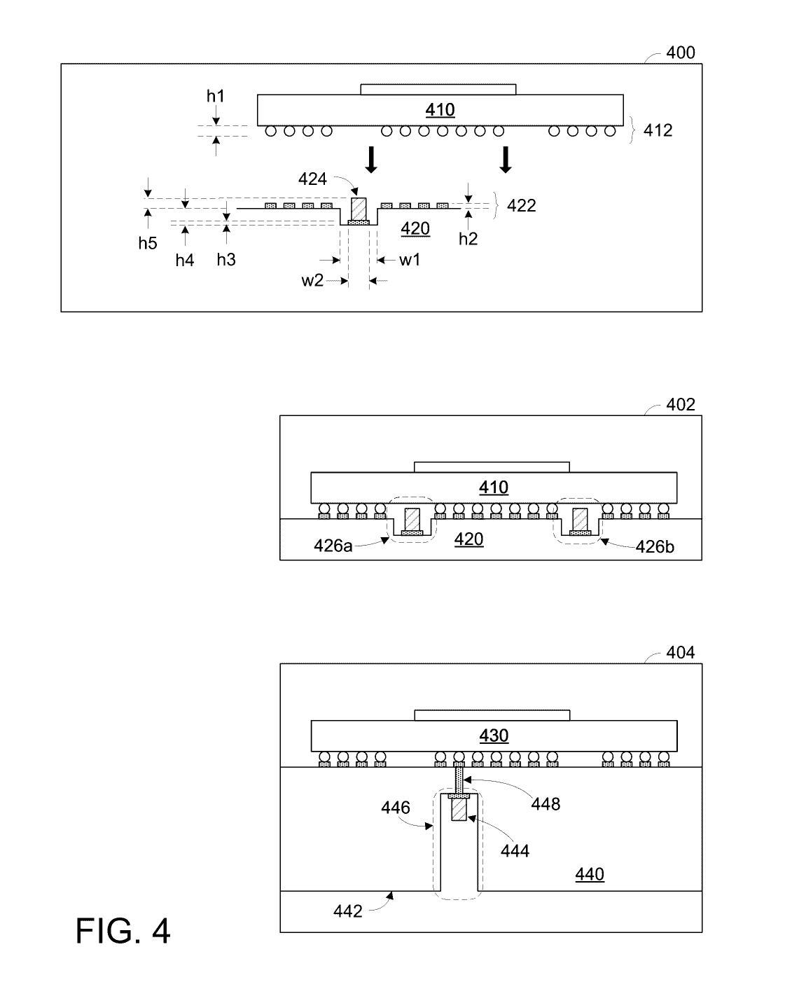

FIG. 4 shows a cross-sectional view 400 of a system to provide connectivity between a packaged device and a capacitor according to an embodiment. The system represented in view 400 may include recess structures such as those variously discussed herein—e.g., where the system includes some of all features of one of systems 100, 300, 350.

In the embodiment illustrated by view 400, a PCB 420 has disposed thereon contacts 422 of a hardware interface, where contacts 422 are to couple PCB 420 to corresponding contacts 412 that comprise a hardware interface of a packaged device 410. PCB 422 forms a recess that extends within a footprint of contacts 422, where the recess has disposed therein another contact (or contacts) to enable coupling of PCB 420 to a capacitor 424. Structural dimensions of the system represented in view 400 may allow for capacitor 424 to be located at least partially in the recess of PCB 420—e.g., where part of capacitor 424 extends above the surface of PCB 420 but below a bottom side of packaged device 410. By way of illustration and not limitation, a height h1 of contacts 412 and a height h2 of contacts 422 may be 0.2 mm and 0.03 mm, respectively. Alternatively or in addition, a height h3 of a contact in the recess may be 0.03 mm—e.g., where a height h4 of the recess is 0.2 mm and a height h5 by which capacitor 424 extends above the recess is 0.1 mm. In such an embodiment, a width w1 of the recess may be 0.6 mm and a width w2 of the contact disposed in the recess may be 0.4 mm. However, these dimensions are merely illustrative or one embodiment, and may vary significantly in other embodiments according to implementation-specific details. By way of illustration and not limitation, some or all such dimensions may be variously larger by up to a factor of 3 and/or smaller by up to 15%.

As shown in cross-sectional view 402, such parameters may allow for vertical clearance between a capacitor located in a recess of PCB 420 and a packaged device 410 that overlaps the capacitor. For example, cross-sectional view 402 shows a system (e.g., the system of view 400) having recesses 426a, 426b in PCB 420, where capacitors each positioned in a respective one of recesses 426a, 426b extend above a side of PCB 420, but remain below a side of the packaged device 410.

Cross-sectional view 404 shows features of an alternative embodiment, wherein a PCB 440 is coupled via contacts of a hardware interface to a packaged device 410. The contacts define a footprint on PCB 440, which forms a recess 446 that is located within an overlap region defined by a projection of the footprint through to an opposite side 442 of PCB 440. A capacitor may be coupled to PCB 440 by a contact that is disposed on a floor of recess 446. The recess 446 may extend from an opening at side 442—e.g., where the floor of recess 446 is farther from side 442 than from the side of PCB 440 to which packaged device 430 is coupled. In the illustrative embodiment shown, a via 448 is directly coupled to the contact in recess 446 and is also directly coupled to one of the contacts coupling PCB 440 to packaged device 410.

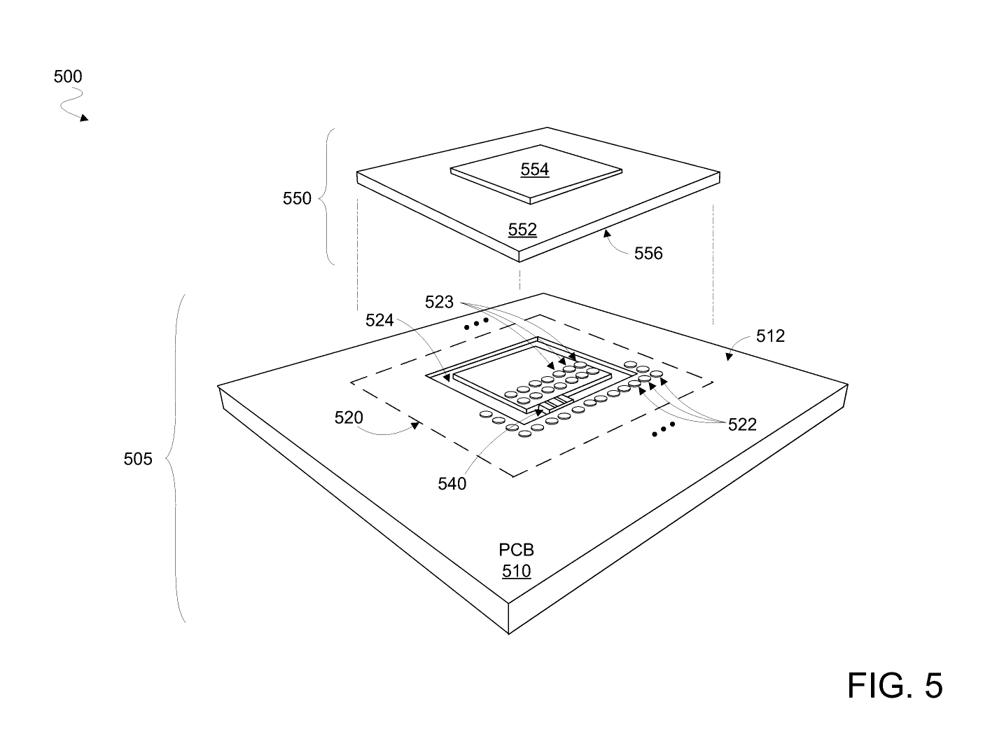

FIG. 5 illustrates elements of a system 500 to couple a packaged device to a capacitor via a substrate according to an embodiment. In the illustrative embodiment shown, system 500 includes an assembly 505 and a package 550, where package 550 is coupled to a capacitor 540 of assembly 505 via a PCB 510 of assembly 505. System 500 may include some or all of the features of system 100, for example. Assembly 505—and, in some embodiments, other elements of system 500—may be manufactured, for example, by operations of method 200. Some embodiments are implemented entirely by PCB 510—e.g., independent of package 550 and/or capacitor 540 being coupled to PCB 510.

A side 512 of PCB 510 may have disposed thereon contacts of a hardware interface to couple PCB 510 to package 550. Such contacts may define a footprint 520 on side 512, where a projection of footprint 520 through PCB 510 defines an overlap region. To avoid obscuring features of some embodiments, not all hardware contacts defining footprint 520 are shown in FIG. 5. In an embodiment, a recess 524 is formed in the overlap region—e.g., where recess 524 extends from side 512 into PCB 510. The recess 524 may form a trench that extends between a first plurality of hardware interface contacts and a second plurality of hardware interface contacts. By way of illustration and not limitation, recess 524 may include a trench structure that loops within an arrangement of contacts 522 of the hardware interface, where the trench surrounds contacts 523 of the hardware interface.

One or more capacitors—e.g., including the illustrative capacitor 540—may be disposed in trench 524. PCB 510 may facilitate connection of capacitor 524 to integrated circuity of package 550. For example, one or more vias, traces and/or other conductors (not shown) of PCB 510 may couple capacitor 540 to one more contacts disposed on side 512. In an embodiment, interconnect structures extending through to a side 556 of a package material 552 of package 550 may aid in connection between such one more contacts on side 512 and an integrated circuit 554 (or other circuitry) of package 550.

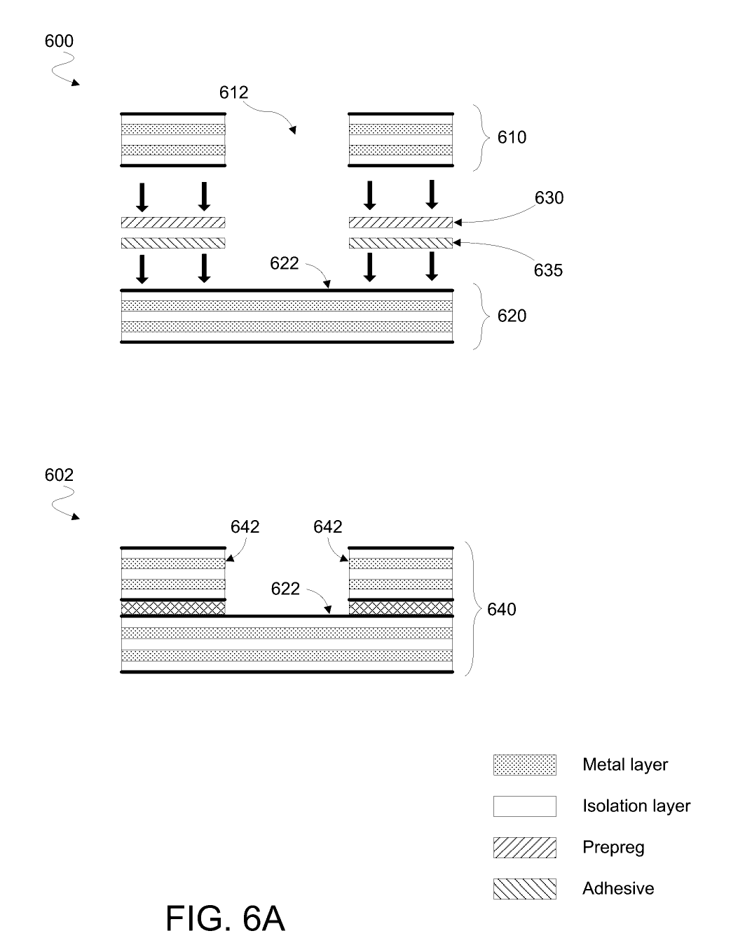

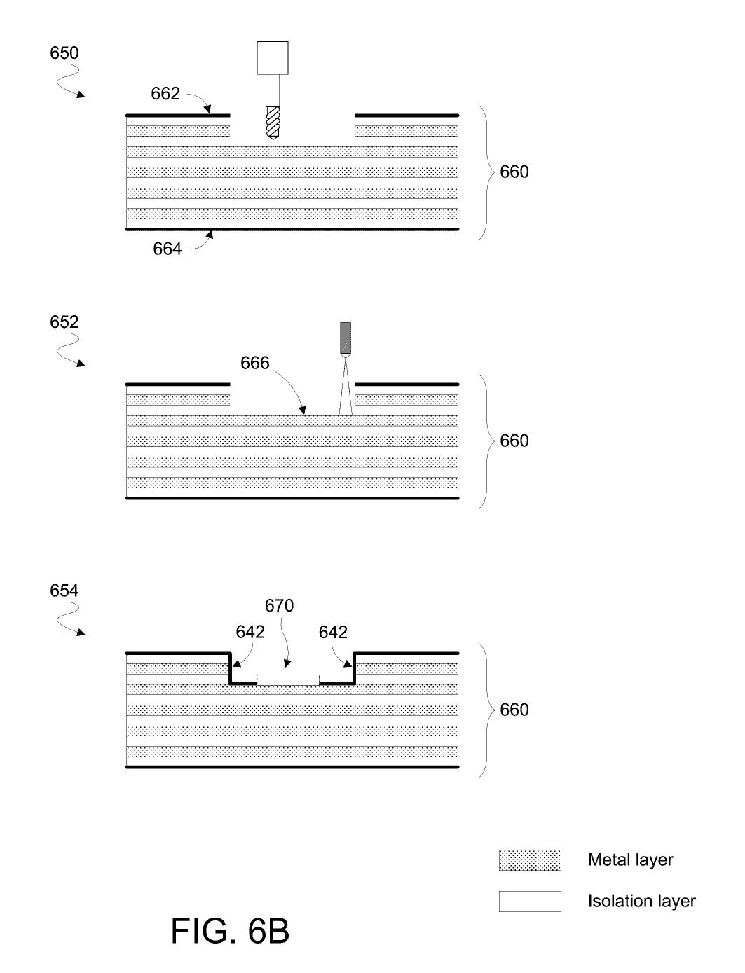

FIG. 6A illustrates stages 600, 602 of processing (e.g., at 220 of method 200) to form a recess in a PCB or other substrate according to one example embodiment. The processing represented in FIG. 6A may form any of various recess structures described herein. At stage 600, lamination sections 610, 620 are aligned for coupling together, where lamination sections 610, 620 each comprise respective metal layers and isolation (e.g., dielectric) layers. The metal layers may variously form signal lines, shielding and/or other conductive structures, where isolation layers of lamination sections 610, 620 include (for example) vias variously interconnecting such metal layers. In one illustrative embodiment, section 610—which forms a hole 612—is laminated to a side 622 of section 620 using, for example, a composite fiber “prepreg” material 630 that is pre-impregnated with an adhesive 635 before lamination of layers 610, 620. At stage 602, lamination of sections 610, 620 is completed to form a substrate 640 having formed therein a recess defined by sidewalls 642 and a floor including a portion of side 622.

FIG. 6B illustrates stages 650, 652, 654 of processing (e.g., at 220 of method 200) according to another example embodiment to form a recess in a substrate. The processing represented in FIG. 6B may form any of various recess structures described herein. At stage 650, mechanical drilling may be performed on a side 662 of a substrate 660 including interleaved metal layers and isolation layers. At some point during processing of substrate 660, one of the opposing sides 662, 664 of of substrate 660 may have disposed thereon contacts (not shown) of a hardware interface to couple a packaged device to substrate 660. The recess may accommodate a capacitor to be coupled to such a packaged device.

The drilling at stage 650 may extend at least partially through an isolation layer—e.g., where laser ablation is further performed at 652 to expose a surface 666 of a metal layer that comprises substrate 660. The exposed surface 666 may provide a contact point for a capacitor (not shown) that is to be disposed in the recess. Additional metal and/or dieletric deposition may selectively cover at least some areas exposed by the processing at stages 650, 652. Such processing may result in the formation, at stage 654, of a contact 670 in a recess defined at least in part by sidewalls 642 of substrate 660.

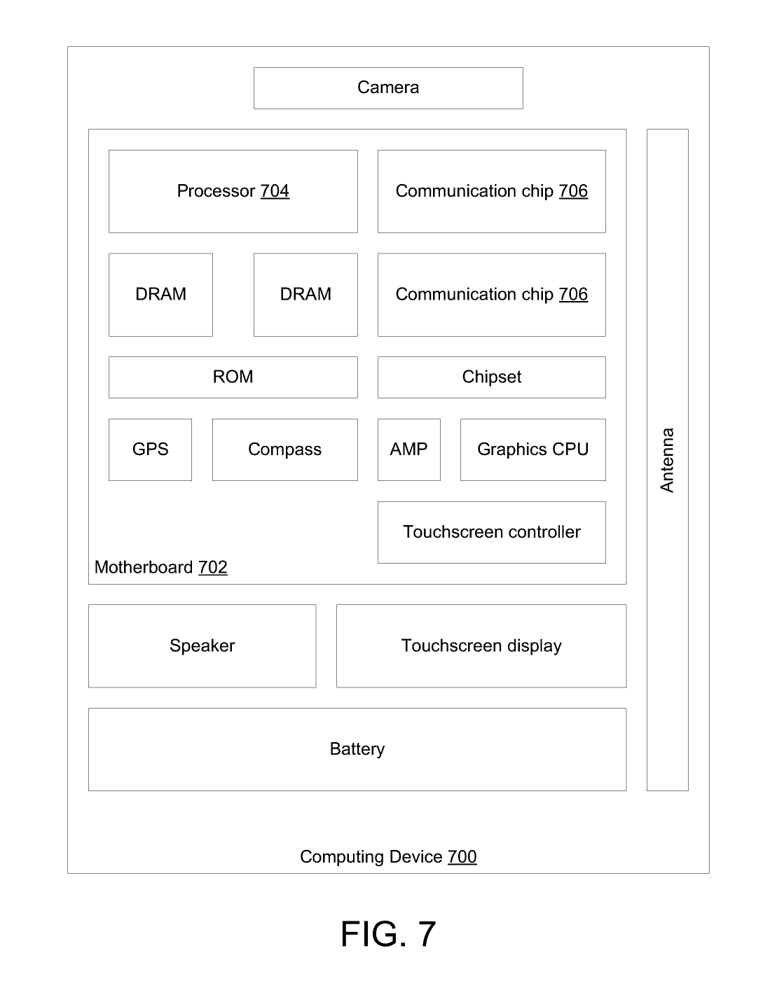

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. The term “processor” may refer to any device or portion of a device that processes electronic data from registers and/or memory to transform that electronic data into other electronic data that may be stored in registers and/or memory. The communication chip 706 also includes an integrated circuit die packaged within the communication chip 706.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

Embodiments of the present invention may be provided as a computer program product, or software, that may include a machine-readable medium having stored thereon instructions, which may be used to program a computer system (or other electronic devices) to perform a process according to embodiments of the present invention. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

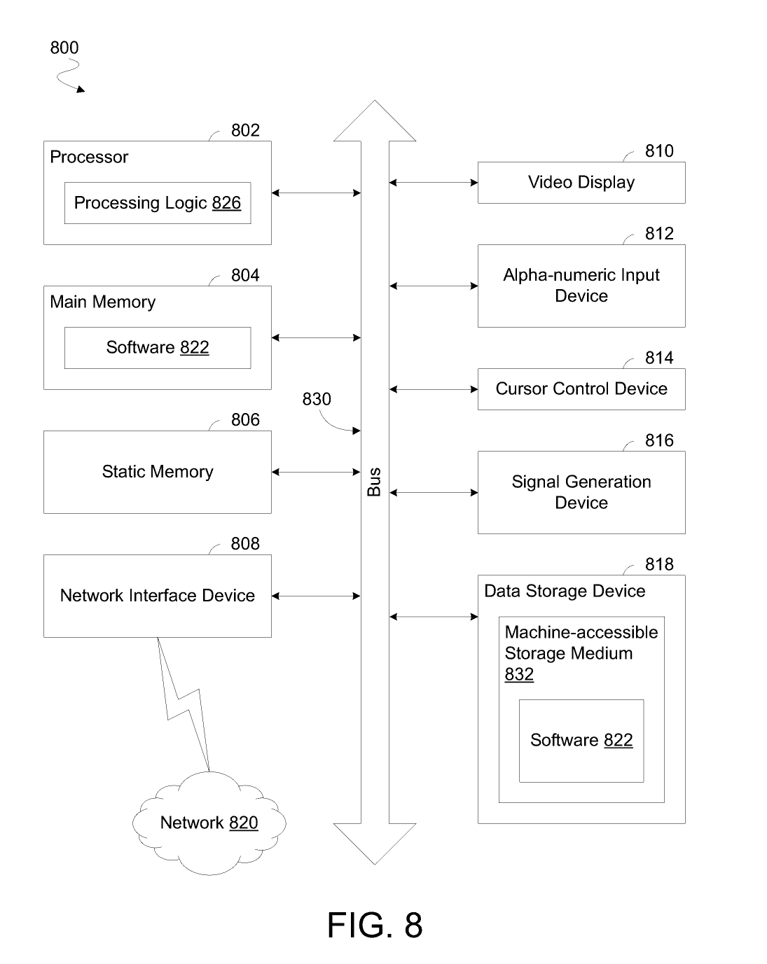

FIG. 8 illustrates a diagrammatic representation of a machine in the exemplary form of a computer system 800 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 800 includes a processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

Processor 802 represents one or more general-purpose processing devices such as a microprocessor, central processing unit, or the like. More particularly, the processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. Processor 802 is configured to execute the processing logic 826 for performing the operations described herein.

The computer system 800 may further include a network interface device 808. The computer system 800 also may include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium (or more specifically a computer-readable storage medium) 832 on which is stored one or more sets of instructions (e.g., software 822) embodying any one or more of the methodologies or functions described herein. The software 822 may also reside, completely or at least partially, within the main memory 804 and/or within the processor 802 during execution thereof by the computer system 800, the main memory 804 and the processor 802 also constituting machine-readable storage media. The software 822 may further be transmitted or received over a network 820 via the network interface device 808.

While the machine-accessible storage medium 832 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

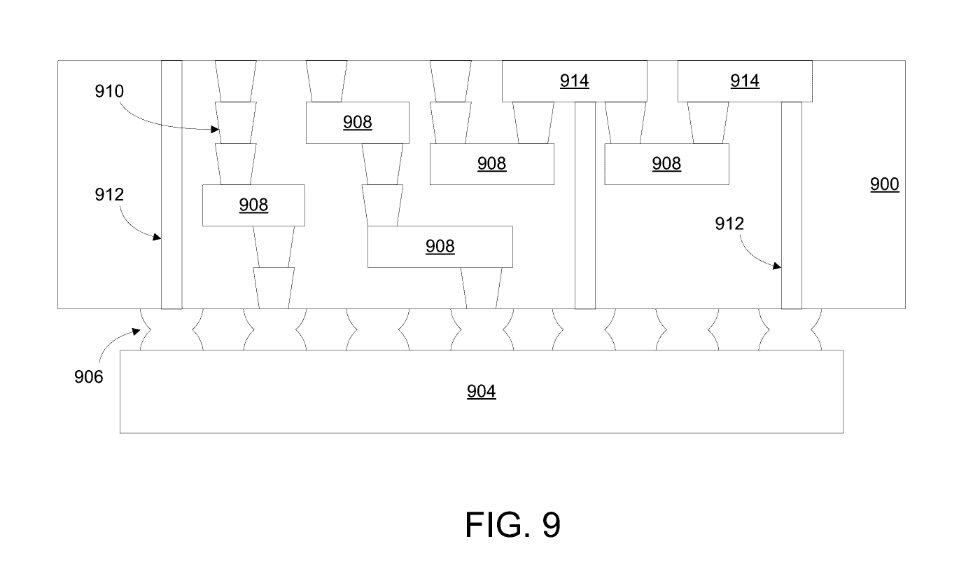

FIG. 9 illustrates an interposer 900 that includes one or more embodiments of the invention. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902, 904 are attached to opposing sides of the interposer 900. In other embodiments, the first and second substrates 902, 904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the invention, apparatuses or processes disclosed herein may be used in the fabrication of interposer 900.

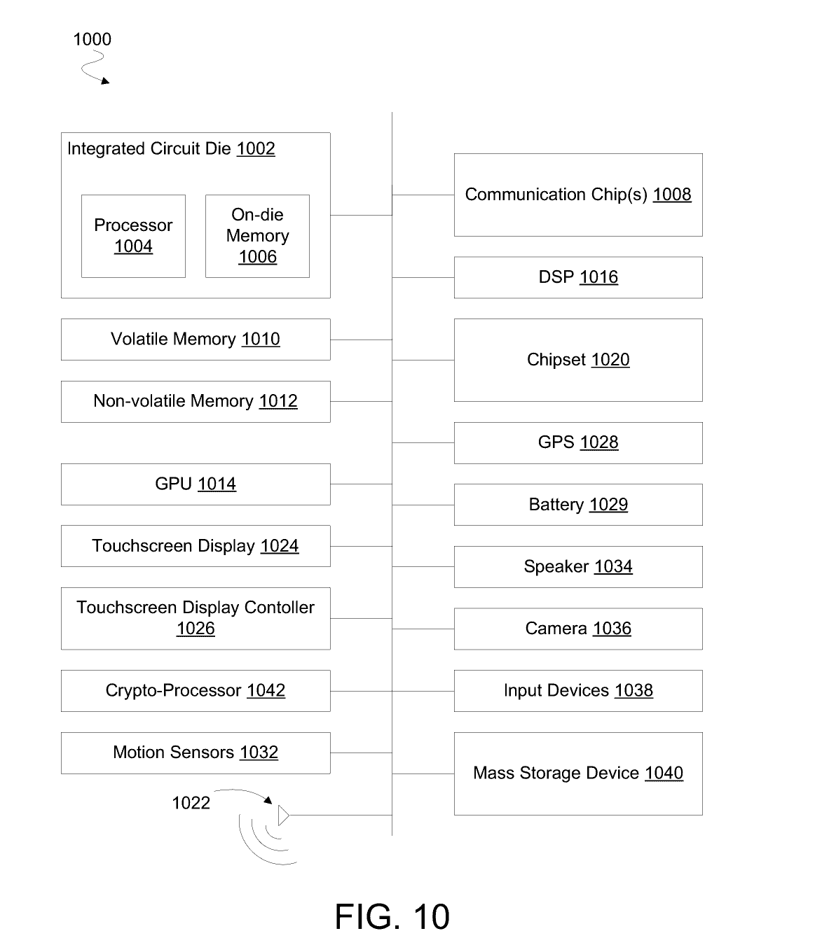

FIG. 10 illustrates a computing device 1000 in accordance with one embodiment of the invention. The computing device 1000 may include a number of components. In one embodiment, these components are attached to one or more motherboards. In an alternate embodiment, these components are fabricated onto a single system-on-a-chip (SoC) die rather than a motherboard. The components in the computing device 1000 include, but are not limited to, an integrated circuit die 1002 and at least one communication chip 1008. In some implementations the communication chip 1008 is fabricated as part of the integrated circuit die 1002. The integrated circuit die 1002 may include a CPU 1004 as well as on-die memory 1006, often used as cache memory, that can be provided by technologies such as embedded DRAM (eDRAM) or spin-transfer torque memory (STTM or STTM-RAM).

Computing device 1000 may include other components that may or may not be physically and electrically coupled to the motherboard or fabricated within an SoC die. These other components include, but are not limited to, volatile memory 1010 (e.g., DRAM), non-volatile memory 1012 (e.g., ROM or flash memory), a graphics processing unit 1014 (GPU), a digital signal processor 1016, a crypto processor 1042 (a specialized processor that executes cryptographic algorithms within hardware), a chipset 1020, an antenna 1022, a display or a touchscreen display 1024, a touchscreen controller 1026, a battery 1029 or other power source, a power amplifier (not shown), a global positioning system (GPS) device 1028, a compass 1030, a motion coprocessor or sensors 1032 (that may include an accelerometer, a gyroscope, and a compass), a speaker 1034, a camera 1036, user input devices 1038 (such as a keyboard, mouse, stylus, and touchpad), and a mass storage device 1040 (such as hard disk drive, compact disk (CD), digital versatile disk (DVD), and so forth).

The communications chip 1008 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1008 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1008. For instance, a first communication chip 1008 may be dedicated to shorter range wireless communications such as Wi-Fi and Bluetooth and a second communication chip 1008 may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. In various embodiments, the computing device 1000 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

In one implementation, a device comprises a substrate and a hardware interface configured to couple the substrate to a packaged integrated circuit (IC) device, the hardware interface including contacts disposed on a first side of the substrate, the first side extending in a first plane, wherein a second side of the substrate extends in a second plane parallel to the first plane, the contacts defining a footprint area in the first plane. The substrate comprises an interconnect extending between a first contact of the contacts and a second contact disposed in a recess formed in the substrate, the recess configured to receive a capacitor, the second contact configured to couple the substrate to the capacitor, wherein the recess extends from the first side or from the second side in an overlap region defined by a projection of the footprint from the first side to the second side in a direction perpendicular to the first plane.

In an embodiment, the recess extends from the second side into substrate. In another embodiment, a floor of the recess is closer to the first side than the second side. In another embodiment, the interconnect includes a via directly coupled to a contact disposed in the recess, the via further directly coupled to the one of the contacts disposed on the first side. In another embodiment, the substrate further comprises another interconnect extending between another contact of the contacts and a third contact disposed in a recess formed in the substrate, the third contact configured to couple to the capacitor.

In another embodiment, the substrate comprises a printed circuit board. In another embodiment, the device further comprises the capacitor. In another embodiment, the device further comprises the packaged IC device. In another embodiment, the contacts include a first plurality of contacts and a second plurality of contacts, and wherein the recess includes a trench extending between first plurality of contacts and the second plurality of contacts. In another embodiment, wherein the trench surrounds a portion of the first side that is in the first plane or surrounds a portion of the second side that is in the second plane. In another embodiment, any sidewall of the substrate that defines a portion of the recess is within the overlap region. In another embodiment, the recess further has disposed therein a third contact to couple to a terminal of the capacitor, wherein the second contact is to couple to another terminal of the capacitor. In another embodiment, the second contact is to couple the other terminal of the capacitor to a reference potential. In another embodiment, a height of the capacitor is less than a height of the recess.

In another implementation, a method comprises forming contacts of a first hardware interface on a first side of a substrate, the first side extending in a first plane, the contacts defining a footprint area in the first plane, wherein the first hardware interface is configured to couple to a second hardware interface of a packaged integrated circuit (IC) device, wherein the first side extends in a first plane and a second side of the substrate extends in a second plane parallel to the first plane. The method further comprises forming in the substrate a recess extending from the first side or from the second side in an overlap region defined by a projection of the footprint from the first side to the second side in a direction perpendicular to the first plane, and forming in the substrate an interconnect extending between a first contact of the contacts and a second contact disposed in the recess, wherein the recess is configured to receive a capacitor, and wherein the second contact is configured to couple the substrate to the capacitor.

In an embodiment, the recess extends from the second side into substrate. In another embodiment, a floor of the recess is closer to the first side than the second side. In another embodiment, the interconnect includes a via directly coupled to a contact disposed in the recess, the via further directly coupled to the one of the contacts disposed on the first side. In another embodiment, the method further comprises forming in the substrate another interconnect extending between another contact of the contacts and a third contact disposed in a recess formed in the substrate, wherein the third contact is configured to couple to the capacitor. In another embodiment, the substrate comprises a printed circuit board.

In another embodiment, the method further comprises coupling the capacitor to the second contact. In another embodiment, the method further comprises coupling the packaged IC device to the substrate via the contacts. In another embodiment, the contacts include a first plurality of contacts and a second plurality of contacts, and wherein the recess includes a trench extending between first plurality of contacts and the second plurality of contacts. In another embodiment, the trench surrounds a portion of the first side that is in the first plane or surrounds a portion of the second side that is in the second plane. In another embodiment, any sidewall of the substrate that defines a portion of the recess is within the overlap region. In another embodiment, the recess further has disposed therein a third contact to couple to a terminal of the capacitor, wherein the second contact is to couple to another terminal of the capacitor. In another embodiment, the second contact is to couple the other terminal of the capacitor to a reference potential.

In another implementation, a method comprises receiving a device including a substrate and a hardware interface including contacts disposed on a first side of the substrate, the first side extending in a first plane, wherein a second side of the substrate extends in a second plane parallel to the first plane, the contacts defining a footprint area in the first plane, wherein the substrate comprises an interconnect extending between a first contact of the contacts and a second contact disposed in a recess formed in the substrate, wherein the recess extends from the first side or from the second side in an overlap region defined by a projection of the footprint from the first side to the second side in a direction perpendicular to the first plane. The method further comprises coupling the substrate to a packaged integrated circuit (IC) device via the contacts, and coupling the capacitor to the second contact, wherein the capacitor extends at least partially into the recess while coupled to the second contact.

In an embodiment, the recess extends from the second side into substrate. In another embodiment, a floor of the recess is closer to the first side than the second side. In another embodiment, the interconnect includes a via directly coupled to a contact disposed in the recess, the via further directly coupled to the one of the contacts disposed on the first side. In another embodiment, the substrate further comprises another interconnect extending between another contact of the contacts and a third contact disposed in a recess formed in the substrate, the third contact configured to couple to the capacitor.

In another embodiment, the substrate comprises a printed circuit board. In another embodiment, the contacts include a first plurality of contacts and a second plurality of contacts, and wherein the recess includes a trench extending between first plurality of contacts and the second plurality of contacts. In another embodiment, the trench surrounds a portion of the first side that is in the first plane or surrounds a portion of the second side that is in the second plane. In another embodiment, any sidewall of the substrate that defines a portion of the recess is within the overlap region. In another embodiment, the recess further has disposed therein a third contact to couple to a terminal of the capacitor, wherein the second contact is to couple to another terminal of the capacitor. In another embodiment, the second contact is to couple the other terminal of the capacitor to a reference potential.

Techniques and architectures for providing structures in or on a printed circuit board are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A device comprising:
a substrate; and
a hardware interface configured to couple the substrate to a packaged integrated circuit (IC) device, the hardware interface including contacts disposed on a first side of the substrate, the first side extending in a first plane, wherein a second side of the substrate extends in a second plane parallel to the first plane, the contacts defining a footprint area in the first plane;
wherein the substrate comprises an interconnect extending between a first contact of the contacts and a second contact disposed in a recess formed in the substrate, the recess configured to receive a capacitor, the second contact configured to couple the substrate to the capacitor, wherein the recess extends from the first side or from the second side in an overlap region defined by a projection of the footprint area from the first side to the second side in a direction perpendicular to the first plane.

2. The device of claim 1, wherein the recess extends from the second side into the substrate.

3. The device of claim 2, wherein a floor of the recess is closer to the first side than the second side.

4. The device of claim 3, wherein the interconnect includes a via directly coupled to a contact disposed in the recess, the via further directly coupled to the one of the contacts disposed on the first side.

5. The device of claim 1, wherein the substrate further comprises another interconnect extending between another contact of the contacts and a third contact disposed in a recess formed in the substrate, the third contact configured to couple to the capacitor.

6. The device of claim 1, wherein the substrate comprises a printed circuit board.

7. The device of claim 1, wherein the contacts include a first plurality of contacts and a second plurality of contacts, and wherein the recess includes a trench extending between first plurality of contacts and the second plurality of contacts.

8. The device of claim 7, wherein the trench surrounds a portion of the first side that is in the first plane or surrounds a portion of the second side that is in the second plane.

9. The device of claim 1, wherein any sidewall of the substrate that defines a portion of the recess is within the overlap region.

10. The device of claim 1, the recess further having disposed therein a third contact to couple to a terminal of the capacitor, wherein the second contact to couple to another terminal of the capacitor.

11. The device of claim 10, wherein the second contact to couple the other terminal of the capacitor to a reference potential.

12. The device of claim 1, wherein a height of the capacitor is less than a height of the recess.

13. A method comprising:
forming contacts of a first hardware interface on a first side of a substrate, the first side extending in a first plane, the contacts defining a footprint area in the first plane, wherein the first hardware interface is configured to couple to a second hardware interface of a packaged integrated circuit (IC) device, wherein the first side extends in a first plane and a second side of the substrate extends in a second plane parallel to the first plane;
forming in the substrate a recess extending from the first side or from the second side in an overlap region defined by a projection of the footprint area from the first side to the second side in a direction perpendicular to the first plane; and
forming in the substrate an interconnect extending between a first contact of the contacts and a second contact disposed in the recess, wherein the recess is configured to receive a capacitor, and wherein the second contact is configured to couple the substrate to the capacitor.

14. The method of claim 13, further comprising forming in the substrate another interconnect extending between another contact of the contacts and a third contact disposed in a recess formed in the substrate, wherein the third contact is configured to couple to the capacitor.

15. The method of claim 13, further comprising coupling the capacitor to the second contact.

16. The method of claim 13, further comprising coupling the packaged IC device to the substrate via the contacts.

17. The method of claim 13, wherein the contacts include a first plurality of contacts and a second plurality of contacts, and wherein the recess includes a trench extending between the first plurality of contacts and the second plurality of contacts.

18. The method of claim 17, wherein the trench surrounds a portion of the first side that is in the first plane or surrounds a portion of the second side that is in the second plane.

19. A method comprising:
receiving a device including:
a substrate; and
a hardware interface including contacts disposed on a first side of the substrate, the first side extending in a first plane, wherein a second side of the substrate extends in a second plane parallel to the first plane, the contacts defining a footprint area in the first plane;
wherein the substrate comprises an interconnect extending between a first contact of the contacts and a second contact disposed in a recess formed in the substrate, wherein the recess extends from the first side or from the second side in an overlap region defined by a projection of the footprint area from the first side to the second side in a direction perpendicular to the first plane;
coupling the substrate to a packaged integrated circuit (IC) device via the contacts; and
coupling a capacitor to the second contact, wherein the capacitor extends at least partially into the recess while coupled to the second contact.

20. The method of claim 19, wherein the substrate further comprises another interconnect extending between another contact of the contacts and a third contact disposed in a recess formed in the substrate, the third contact configured to couple to the capacitor.

21. The method of claim 19, wherein the substrate comprises a printed circuit board.

22. The method of claim 19, wherein any sidewall of the substrate that defines a portion of the recess is within the overlap region.
